(19) United States
(12) Patent Application Publication
(10) Pub. No.: US 2009/0057806 A1
(43) Pub. Date: Mar. 5, 2009

(54) SEGMENTED PHOTODIODE

(75) Inventor: Masaki MATSUDA, Kawasaki (JP)

Correspondence Address: YOUNG & THOMPSON, 209 Madison Street, Suite 500, ALEXANDRIA, VA, 22314, US

(73) Assignee: NEC ELECTRONICS CORPORATION, Kawasaki (JP)

(21) Appl. No.: 12/204,078

(22) Filed: Sep. 4, 2008

(30) Foreign Application Priority Data
Sep. 4, 2007 (JP) 2007-228800

(51) Int. Cl. H01L 31/02

(52) U.S. Cl. 257/466; 257/E31.11

(57) ABSTRACT

In one embodiment of the present invention, the segmented photodiode includes a p type substrate, a p type epitaxial layer formed on the p type substrate, an n type epitaxial layer formed on the p type epitaxial layer, and p type segmenting region provided in the n type epitaxial layer separately from the p type epitaxial layer and segmenting the photosensitive region, and is configured that a depleted layer (first depleted layer) created in an n type region right under the segmenting section located between the p type segmenting region and the p type epitaxial layer by applying a reverse bias voltage is configured to reach a depleted layer (second depleted layer) formed in a junction surface between the n type epitaxial layer and the p type epitaxial layer so that the photosensitive region is electrically isolated.

This application is based on Japanese patent application No, 2007-228,800, the content of which is incorporated hereinto by reference.

### BACKGROUND

1. Technical Field

The present invention relates to a segmented photodiode having a photosensitive region that is capable of receiving light, which is two-dimensionally segmented into multiple areas.

2. Related Art

In optical pickup devices that read out information stored in optical disks such as a compact disk (CD), a digital video disc (DVD) and the like, a disc is irradiated with a laser beam and reflected light is detected with the photodiode to achieve a process for reading out information.

For example, Japanese Patent Laid-Open No. H5-145,107 (1993) discloses a common-cathode photodiode having an n type well region formed under p+based anode regions extending from the surface of the substrate so as to be associates with the respective anode regions, which achieves higher sensitivity for incident light and improved prevention for cross talk between respective diodes.

Japanese Patent Laid-Open No. 2001-135,849 discloses a photodiode, in which a p+ surface diffusion layer is formed in an n type semiconductor layer to have a predetermined pattern containing belt regions to reduce the diffusion travelling time of career generated in the semiconductor layer without considerably increasing a PN junction area, and n+ diffusion layer is disposed between the belt regions of the p+ surface diffusion layer to reduce the cathode resistance.

On the other hand, segmented photodiodes having a photosensitive region composed of a plurality of segmented photodetecting sections are employed in recent years as devices for detecting signals in optical pickup processes. Such segmented photodiode is capable of detecting better defocusing signals or tracking error signals on the basis of signal difference from respective photo acceptor units of the segmented photosensitive regions. Consequently, precise reproduction of a plurality of different optical disks can be achieved by employing such technology.

Japanese Patent laid-Open No. 2000-82,226 discloses, for example, a typical conventional segmented photodiode. A segmented photodiode disclosed in Japanese Patent Laid-Open No. 2000-82,226 is shown in FIG. 7. Such segmented photodiode has photosensitive surfaces 200, 201, 202, each of which is segmented into four regions.

This segmented photodiode is composed of a photodiode and an integrated circuit that amplifies a signal from the photodiode, both of which are formed in one silicon substrate.

Light reflected by the disc is entered to the segmented surfaces, in addition to the respective segmented photosensitive regions shown as FIG. 7. Further, a rapid response is required for the segmented photodiode, due to increased rates of read out from/writing to an optical disk. Thus, rapid responses for lights entered to the segmented surface are required for the photodiode.

Japanese Patent Laid-Open No. H9-153,605 (1997) and Japanese Patent Laid-Open No. H10-270,744 (1998) also disclose photodiodes having segmented photosensitive regions, similarly as the segmented photodiodes described in Japanese Patent Laid-Open No. 2000-82,226.

However, the conventional technologies described in the above literature need to be improved in terms of the following points.

A cross-sectional view of a segmented photodiode disclosed in Japanese Patent Laid-Open No. H9-153,605 is shown in FIG. 8A. The cross-sectional view of such segmented photodiode 100 is shown to represent regions corresponding to photosensitive regions D1, D2, D3 and D5. A p type isolation diffusion layer 5 (splitting) is buried in a p type semiconductor substrate 1 extending through and n type epitaxial layer 4.

In case of such structure of the photodiode, no depleted layer is generated around the segmenting sections, and a region without being applied with an electric field is present. Consequently, responses of the segmenting sections are deteriorated over the n type epitaxial layer 4.

FIG. 8B shows results of simulations for behaviors of photocarrier in the segmented photodiode described in Japanese Patent Laid-Open No. H9-153,605. Small arrows appeared in FIG. 8B indicates directions of electric currents, and electrons serving as photocarrier travel toward directions inverse to the arrows. As shown in FIG. 8B, lines indicated as “depleted layer edge” are present in both sides of a segmenting section, and no depleted layer is generated right under the segmenting section and its circumference.

A cross-sectional view of a segmented photodiode disclosed in Japanese Patent Laid-Open No. H10-270,744 is shown in FIG. 8C. A structure of the segmented photodiode disclosed in Japanese Patent Laid-Open No. H10-270,744 provides an improvement in a problem of increased serial resistance of photodiodes by adopting an epitaxial layer having higher specific resistance in the segmented photodiode described in Japanese Patent Laid-Open No. H9-153,605. In the segmenting section of such structure, however, a p type isolation diffusion region 5 (segmenting section) is buried in a p type semiconductor substrate 11 having higher specific resistance extending through an n type epitaxial layer 4. Consequently, it is considered that no depleted layer is generated right under the segmenting section and its circumference, similarly as in the structure of Japanese Patent Laid-Open No. H9-153,605.

Since no depleted layer is generated right under the p type segmenting region and its circumference and a region without being applied with an electric field is present in conventional segmented photodiodes as described above, carrier generated in the p type semiconductor layer by a light entered to the segmenting section travels via a diffusion right under the segmenting section. Consequently, drift speed is decreased, leading to a reduced speed of response.

The present inventor has discovered an enhanced speed of response of a segmented photodiode by extending the depleted layer right under the segmented region and the circumference right under the segmented region.

### SUMMARY

According to one aspect of the present invention, there is provided a segmented photodiode having a photosensitive region being capable of receiving light, the photosensitive region being two-dimensionally segmented into multiple areas, comprising: a substrate of a first type conductivity; a first semiconductor layer of the first type conductivity formed on the substrate; a second semiconductor layer of a second type conductivity formed on the first semiconductor layer; and a segmenting section of first type conductivity, provided in the second semiconductor layer spaced apart from the first semiconductor layer and providing segmentation of the photosensitive region, wherein a first depleted layer is formed between the segmenting section and the first semiconductor layer by applying a reverse bias voltage, and wherein the first depleted layer is configured to reach a second depleted layer formed in a junction surface between the second semiconductor layer and the first semiconductor layer so that the photosensitive region is electrically isolated.

According to the above-described aspect of the present invention, the segmenting section of the first type conductivity is provided in the second semiconductor layer of the second type conductivity spaced apart from the first semiconductor layer of the first type conductivity. This allows forming the first depleted layer between the segmenting section and the first semiconductor layer in operating the device, and reaching the second depleted layer formed in a junction surface created by PN junctions of the first semiconductor layer and the second semiconductor layer to electrically isolate in photosensitive region. Further, since the segmenting section does not reach the first semiconductor layer, the second depleted layer extends over the entire area of the PN junction without being separated right under the segmenting section to provide larger photosensitive regions. Consequently, improved speed of response of the segmented photodiode can be achieved while maintaining the functions for the segmented photodiode.

Here, for example, the “first type conductivity” may be p type and the “second type conductivity” may be n type, and vice versa, that is, the “first type conductivity” may be n type and the “second type conductivity” may be p type.

In the present invention, the segmenting section may be configured to be composed of a diffusion layer containing impurity of first type conductivity diffused therein. The diffusion layer means a region created by diffusing impurity in a predetermined region.

Further, in the present invention, the photosensitive region means a PN junction formed in an interface of the first semiconductor layer with the second semiconductor layer.

Further, in the present invention, the photosensitive region may be configured of a plurality of small regions that are electrically isolated by the segmenting section and the second depleted layer is formed over the entire area of the photosensitive region. This allows the carrier traveling at a higher rate, achieving a rapid response.

According to the present invention, a segmented photodiode with an improved speed of response is presented.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A and 1B are diagrams that schematically illustrate a segmented photodiode according to an embodiment, and FIG. 1A is a plan view, schematically illustrating the segmented photodiode according to the embodiment, and FIG. 1B is a cross-sectional view along line A-A in FIG. 1A;

FIGS. 2A to 2C are cross-sectional views, illustrating an exemplary implementation of a process for manufacturing the segmented photodiode according to the embodiment;

FIGS. 3A and 3B are cross-sectional views, schematically illustrating a segmented photodiode of comparative example;

FIGS. 4A to 4C are cross-sectional views, illustrating an exemplary implementation of a process for manufacturing the segmented photodiode of a comparative example;

FIG. 5A is a diagram, illustrating an irradiated surface of light, and FIG. 5B is a graph, showing results of the frequency response;

FIGS. 6A to 6C includes diagrams, useful in describing the advantageous effects of the segmented photodiode of the embodiment, and FIG. 6A is a diagram of an electric potential distribution of the embodiment, FIG. 6B is a diagram of an electric potential distribution of comparative example, and FIG. 6C is a graph, showing a relationship of a distance from the photosensitive surface with an electric potential;

FIG. 7 is a schematic diagram, illustrating a conventional segmented photodiode; and

FIG. 8A to 8C are schematic diagrams that illustrate a conventional segmented photodiode, and FIG. 8A is a cross-sectional view, schematically illustrating the conventional segmented photodiode, FIG. 8B is a diagram, useful in describing the conventional segmented photodiode, and FIG. 8C is a cross-sectional view, schematically illustrating a conventional segmented photodiode.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Exemplary implementations according to the present invention will be described in detail as follows in reference to the annexed figures. In all figures, an identical numeral is assigned to an element commonly appeared in the figures, and the detailed description thereof will not be repeated.

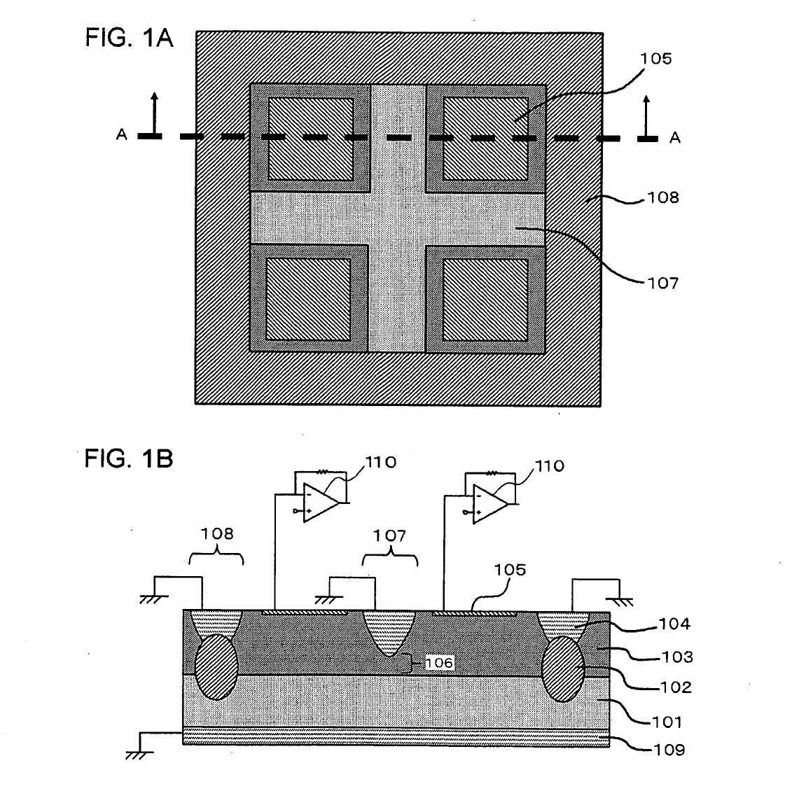

FIGS. 1A and 1B are diagrams that schematically illustrate a segmented photodiode of the present embodiment. FIG. 1A is a plan view, schematically illustrating the segmented photodiode of the present embodiment. FIG. 1B is a cross-sectional view along line A-A shown in FIG. 1A.

The segmented photodiode of the present embodiment is a segmented photodiode including a photosensitive region for receiving light, which is two-dimensionally segmented into four segmented areas. Each of segmented areas is connected to an amplifier 110 respectively as shown in FIG. 1B. This segmented photodiode includes a p type substrate 109, a p type epitaxial layer 101 formed on the p type substrate 109, an n type epitaxial layer 103 formed on the p type epitaxial layer 101, and p type segmenting region 107 provided in the n type epitaxial layer 103 separately from the p type epitaxial layer 101 and segmenting the photosensitive region.

Further, the segmented photodiode of the present embodiment is configured that an n type region 106 right under the segmenting section located between the p type segmenting region 107 and the p type epitaxial layer 101 is depleted by applying a reverse bias voltage, and the depleted layer created in the n type region 106 right under the segmenting section (first depleted layer) is configured to reach a depleted layer (second depleted layer) formed in a junction surface between the n type epitaxial layer 103 and the p type epitaxial layer 101 so that the segmented areas are electrically isolated from each other. The reverse bias voltage is applied by the amplifiers 110 connecting to each of the segmented areas respectively. And each of segmented areas operates as a photodiode electrically isolated from each other.

Further, the segmented photodiode of the present embodiment further includes a p type isolation region 108 surrounding the photosensitive region that is two-dimensionally segmented. The p type isolation region 108 is provided over a surface of the p type epitaxial layer 101 and a surface of the n type epitaxial layer 103. The p type isolation region 108 is continually provided without separating the surface of p type epitaxial layer 101 and the surface of the n type epitaxial layer 103.

Further, the segmented photodiode of the present embodiment is configured that the p type isolation region 108 and the p type substrate 109 forms a common-anode.

The p type segmenting region 107 is composed of a p type diffusion layer 104 containing p type impurity diffused therein. The p type diffusion layer 104 is created by diffusing p type impurity in a predetermined region. Typical p type impurity includes boron.

Further, the p type isolation region 108 is provided in the p type epitaxial layer 101. It includes the p type diffusion layer 104 containing p type impurity diffused therein and a p type buried layer 102 buried within the n type epitaxial layer 103 and the p type epitaxial layer 101. In the p type isolation region 108, the p type diffusion layer 104 is coupled to the p type buried layer 102.

The p type isolation region 108 picks up a substrate electric potential of the photodiode. The presence of the p type buried layer 102 allows picking up the substrate electric potential of the segmented photodiode without forming a depleted layer under the p type isolation region 108. Consequently, improved frequency characteristics of the photodiode can be achieved, without an increase in the serial resistance of the photodiode due to a creation of a depleted layer.

Further, an n type diffusion layer 105 containing n type impurity diffused therein is provided in the surface of the n type epitaxial layer 103 in the segmented photodiode of the present embodiment. The n type diffusion layer 105 is created by diffusing n type impurity in a predetermined region. Typical n type impurity includes phosphorus and arsenic.

The photosensitive region is configured of four small regions, which are electrically isolated by the p type segmenting region 107. A depleted layer is formed over the entire area of the photosensitive region.

The p type segmenting region 107 is cross-shaped in two-dimensional view, and two-dimensionally isolates the photosensitive region into four sections. This allows providing four segmented regions of the photosensitive region, so that a focus error signal can be obtained by an astigmatism process. An arrangement of the p type segmenting region 107 is suitably designed, so that a suitable segmentation of the photosensitive region can be achieved depending on the purposes.

Further, the segmented photodiode of the present embodiment may includes a plurality of photosensitive structural units, each which is composed of the photosensitive region and the p type isolation region 108 surrounding the photosensitive region.

A quantity of the photosensitive structural units is not particularly limited. For example, the photosensitive region of the segmented photodiode of the present embodiment is segmented into four sections by the cross-shaped p type segmenting region 107. Consequently, a use of three photosensitive structural units provides the photosensitive region segmented into 12 sections. The use of three photosensitive structural units allows containing a tracking error signal by a 3-beam technique (3-spot technique). The three photosensitive structural units may be, for example, arranged along a straight line.

A thickness of the n type region 106 right under the segmenting section may be designed, so that the n type region 106 right under the segmenting section is depleted by applying a reverse bias voltage to reach a depleted layer formed in a junction surface of the n type epitaxial layer 103 and the p type epitaxial layer 101. For example, under the conditions that the impurity concentration of the n type epitaxial layer 103 is selected to be 5×10¹⁵ cm⁻¹ and the impurity concentration of the p type epitaxial layer 101 is selected to be 1×10¹⁴ cm⁻³, when a reverse bias voltage of 2.1 V is applied, a depleted layer (first depleted layer) formed in the n type region 106 right under the segmenting section reaches to a location of 2.0 μm deep from the surface of the n type epitaxial layer 103, and a depleted layer (second depleted layer) created in a junction surface of the n type epitaxial layer 103 with the p type epitaxial layer 101 reaches to a location of 1.0 μm above from such junction surface. In this case, it is preferable to select the thickness of the n type epitaxial layer 103 to be 3.0 μm or thinner, and more preferably 2.5 μm in consideration of a practical utility thereof. This allows connecting the first depleted layer and the second depleted layer, thereby providing the segmentation of the photosensitive region.

Subsequently, an operation of the segmented photodiode of the present embodiment will be described. In such segmented photodiode, the p type epitaxial layer 101 and the p type isolation region 108 function as anodes, and the n type diffusion layer 105 and the n type epitaxial layer 103 function as cathodes.

When the segmented photodiode of the present embodiment is operated, the p type diffusion layer 104 of the p type isolation region 108 serving as the anode is grounded, an a reverse bias of about 2.1 V is applied to the n type epitaxial layer 103 serving as the cathode. Such bias voltage allows the PN junction of the p type epitaxial layer 101 with the n type epitaxial layer 103 creating a depleted layer, and thus in a condition of being applied with an electric field.

In such case, the p type segmenting region 107 is buried in the n type epitaxial layer 103 so that a bottom surface thereof is in contact with the n type epitaxial layer 103, without extending through the n type epitaxial layer 103. Consequently, this leads to the depleted layer being formed over the entire area of the PN junction located inside of the p type isolation region 108, without being separated by the p type segmenting region 107.

Further, since the p type segmenting region 107 is provided above the surface of the p type epitaxial layer 101, a depleted layer is also generated in the n type region 106 right under the segmenting section right under the p type diffusion layer 104 of the p type segmenting region 107. This allows extending the electric field created by an applied voltage between the anode and the cathode to the location right under thereof. Consequently, the photosensitive region, which is configured of the interface of the p type epitaxial layer 101 and the n type epitaxial layer 103, is two-dimensionally segmented in the operation.

Therefore, the photosensitive region is electrically segmented into four regions. Further, the p type isolation region 108 and the p type substrate 109 serve as common-anode. The “common-anode” indicates that the respective cathodes of the segmented photodiode are electrically isolated, and the anodes are electrically mutually coupled. In the present embodiment, the anodes of the respective photodiodes are fixed to the ground (GND).

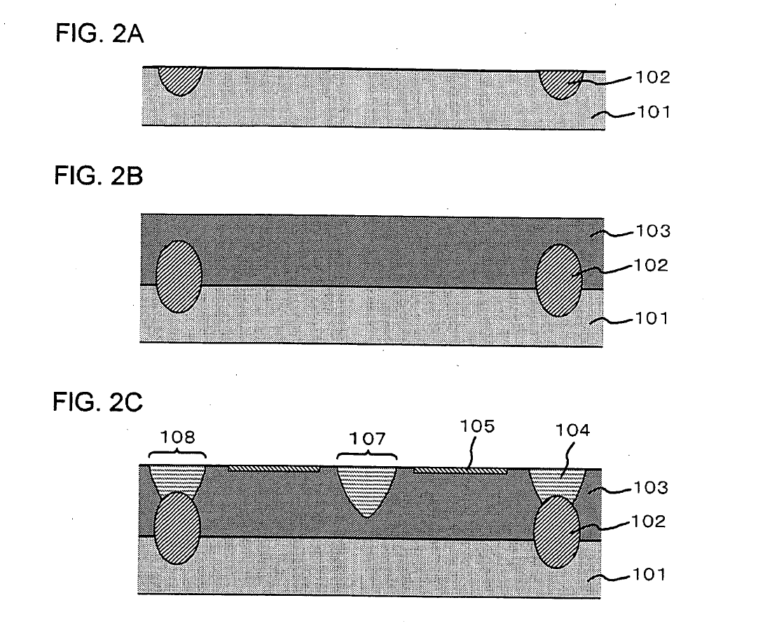

Next, a process for manufacturing the segmented photodiode of the present embodiment will be described in reference to FIGS. 2A to 2C. The p type epitaxial layer 101 is grown on the p type substrate 109 composed of a silicon substrate, and then the p type buried layer 102 is formed in a location for creating the p type isolation region 108. In such case, the p type buried layer 102 is not formed in a location for creating the p type segmenting region 107 (FIG. 2A). Next, the n type epitaxial layer 103 is grown. In this case, the p type buried layer 102 of the p type isolation region 108 extends to the region of the n type epitaxial layer 103 via a thermal diffusion (FIG. 2B). Next, a process such as ion implanting process from the surface and the like is employed to form the p type diffusion layer 104, creating the p type segmenting region 107 and the p type isolation region 108 (FIG. 2C).

Before and/or after, or during such manufacturing process, a part of or the whole of, a process for manufacturing an integrated circuit including bipolar transistors, resistors and the like may be additionally included.

Further, when the p type diffusion layer 104 is formed, it is often occurred that the thickness of the n type epitaxial layer 103 is too thin, such that the p type diffusion layer 104 reaches the p type epitaxial layer 101. In this case, the p type diffusion layer 104 for the p type segmenting region 107 can be formed to be shallower, as compared with the p type diffusion layer 104 for the p type isolation region 108 by suitably controlling an accelerating energy in the ion implantation process. This procedure allows manufacturing the segmented photodiode of the present embodiment.

Next, advantageous effects obtainable by employing the configuration of the present embodiment will be described. According to the segmented photodiode of the present embodiment, the bottom surface of the p type segmenting region 107 is provided so as to be in contact with the n type epitaxial layer 103. This allows the first depleted layer being formed between the p type segmenting region 107 and the p type epitaxial layer 101 in operating the device, and also allows the first depleted layer reaching the second depleted layer formed in a junction surface created by PN junctions of the p type epitaxial layer 101 and the n type epitaxial layer 103 to electrically isolate in photosensitive region.

Further, no portion of the p type segmenting region 107 extends through the n type epitaxial layer 103 to reach the p type epitaxial layer 101. This allows the depleted layer that is created by the PN junction between the p type epitaxial layer 101 and the n type epitaxial layer 103 extending to the location right under the p type segmenting region 107 and to the circumferences of the location right under the p type segmenting region 107, thereby providing an increased dimensional area of the photosensitive region.

Further, in the present embodiment, the photosensitive region is configured of four small regions that are electrically isolated by the p type segmenting region 107. On the other hand, the depleted layer is formed over the entire area of the photosensitive region. The larger dimensional area of the depleted layer allows the career created by an incidence of light traveling at higher speed.

Therefore, according to configuration of the segmented photodiode of the present embodiment, improved speed of response of the segmented photodiode can be achieved while maintaining the functions for the segmented photodiode.

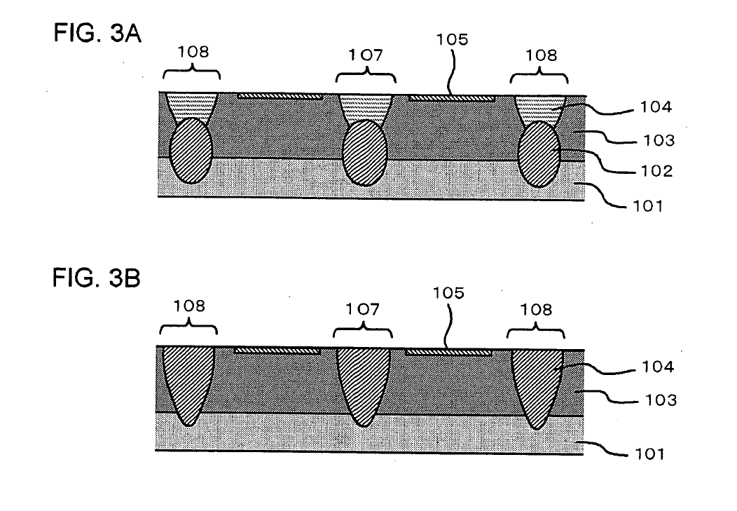

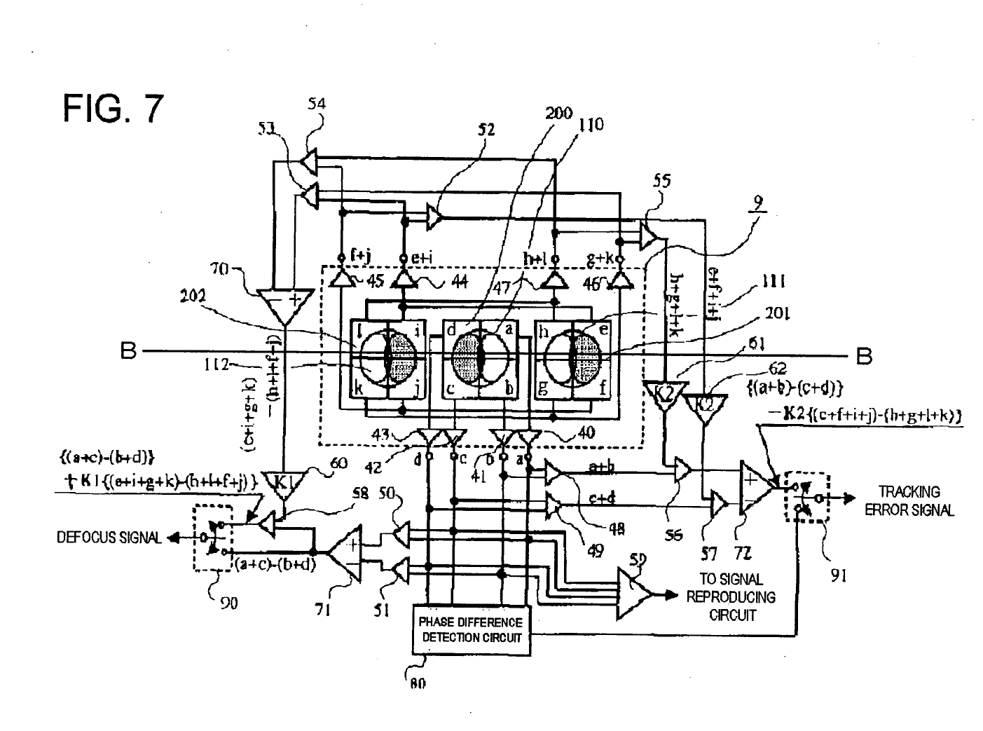

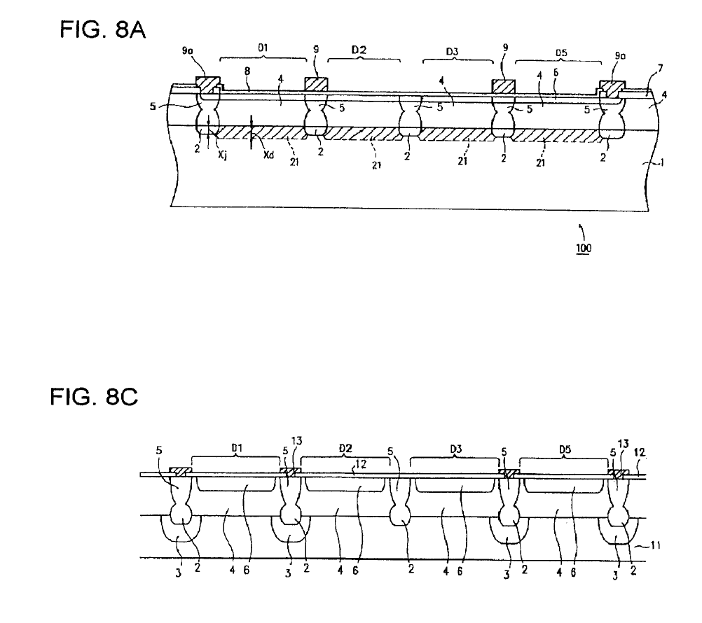

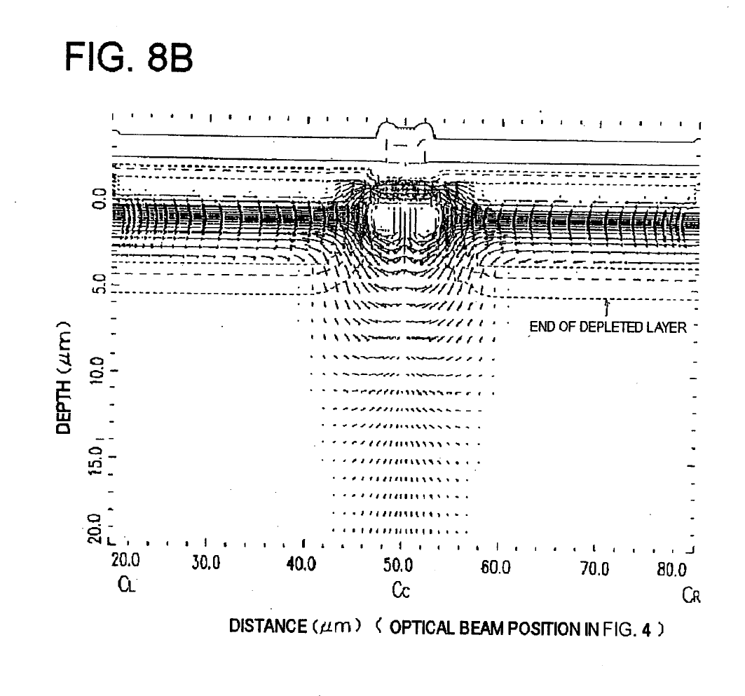

FIGS. 3A and 3B are cross-sectional views, schematically illustrating a comparative example of a segmented photodiode for the purpose of comparisons in the present embodiment. FIGS. 3A and 3B show a cross section of a photosensitive surface of a conventional segmented photodiode (along line B-B of FIG. 7). The p type epitaxial layer 101 and the p type isolation region 108 function as anode, and the a type diffusion layer 105 and the n type epitaxial layer 103 function as cathode, constituting a photodiode. Further, the cathode configured of the n type diffusion layer 105 and the n type epitaxial layer 103 is segmented by the p type segmenting region 107 to form a photodiode having segmented regions.

Such p type segmenting region 107 may be configured of the p type diffusion layer 104 and the p type buried layer 102 as shown in FIG. 3A, or may be configured of only the p type diffusion layer 104 as shown in FIG. 3B.

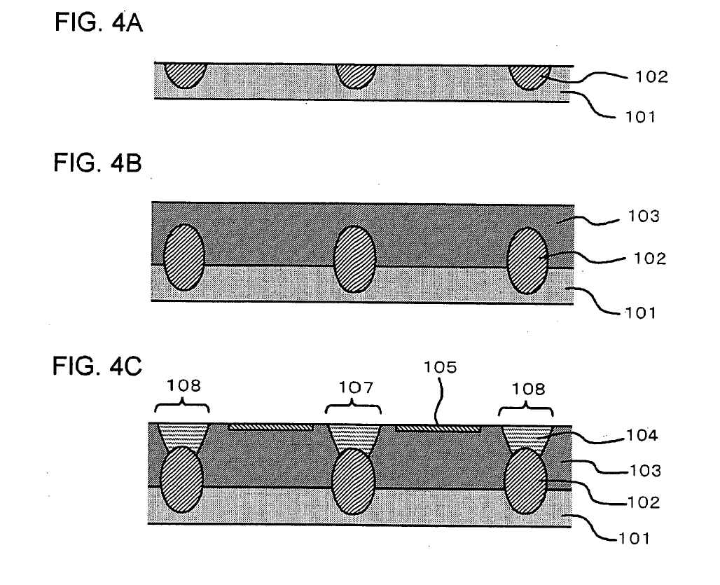

A process for manufacturing the segmented photodiode in the comparative example shown in FIG. 3A is illustrated in FIGS. 4A to 4C. The p type epitaxial layer 101 is grown on the semiconductor substrate (not shown), and the p type buried layer 102 is formed in a location for forming the p type isolation region 108. Next, the n type epitaxial layer 103 is grown. In this case, the p type buried layer 102 extends to the region of the n type epitaxial layer 103 via a thermal diffusion. Next, a process such as ion implanting process from the surface and the like is employed to form the p type diffusion layer 104 in the p type isolation region 108 and the p type segmenting region 107, creating the p type segmenting region 107 and the p type isolation region 108.

The p type diffusion layer 104 in the p type isolation region 108 is formed to be deeper than the upper end of the p type buried layer 102. Further, the p type buried layer 102 is united with the p type diffusion layer 104. The p type isolation region 108 is configured that the n type epitaxial layer 103 is isolated by the p type diffusion layer 104 and the p type buried layer 102.

In operation of such photodiode, the anode is grounded and a reverse bias of around 2.1 V is applied to the cathode. Such bias voltage allows the p type epitaxial layer and the n type epitaxial layer creating a depleted layer, and thus in a condition of being applied with an electric field, so that generated career can migrate at higher speed.

As shown in FIGS. 3A and 3B, the p type segmenting region 107 extends from its surface through the p type epitaxial layer 101 in the photodiode of comparative example. Thus, no PN junction exists in the p type segmenting region 107 itself, and therefore no depleted layer due to the bias voltage is generated, creating no electric field. The reason for a deterioration of the response characteristics when the p type segmenting region 107 is irradiated with light is that the career generated in the p type epitaxial layer 101 under the p type segmenting region 107 detours around the p type segmenting region 107 and then reaches the end of the depleted layer of the PN junction. The PN junction is formed of an interface of the n type epitaxial layer 103 with the p type epitaxial layer 101. Therefore, the photocarrier generated under the p type segmenting region 107 is required to migrate via diffusion until reaching the end of the depleted layer. The drift speed via diffusion is slower, leading to degradation in the response characteristics.

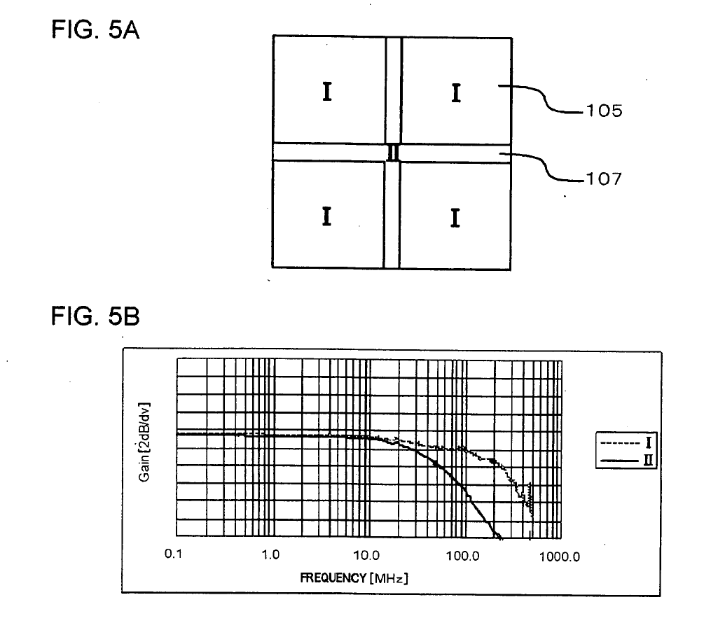

FIGS. 5A and 5B illustrates results of frequency response obtained by employing the segmented photodiode of comparative example. FIG. 5A is a diagram, illustrating an irradiated surface of light. The mark “I” represents the surface of the n type diffusion layer 105. The mark “II” represents a surface of the p type segmenting region 107. FIG. 5B is a graph, showing results of the frequency response. The ordinate of the graph represents gain (2 dB/dv), and the abscissa represents frequency. The measurements of the frequency response were conducted under the conditions of: reverse bias of 2.1 V; load resistance of 50Ω, and light wavelength of 780 nm.

Cut-off frequency is determined as a frequency, in which the gain is decreased by 3 dB as compared with the gain at lower frequency. As can be seen from FIG. 5B, the cut-off frequency when the area “I” is irradiated with light is about 200 MHz, and on the other hand, the cut-off frequency when the p type segmenting region 107 indicated by “II” is irradiated with light is about 50 MHz. Therefore, it is considered that the response characteristics in the p type segmenting region 107 are deteriorated.

A frequency of a signal utilized in a system of compact disk (CD) employing light having a wavelength of 780 nm is 0.72 MHz at the maximum rate, and 1.44 MHz at double speed reading, and 2.88 MHz at quad speed reading. Thus, a constant gain from low-frequency to 36 MHz is required for a photodiode employed for a fiftyfold speed-reading CD system. Nevertheless, the gain of the photodiode of comparative example is reduced by about 2 dB. Thus, when the photodiode of comparative example is used for a fiftyfold speed-reading CD system, normal reproductive signal may not possibly be obtained, due to such degradation of gain.

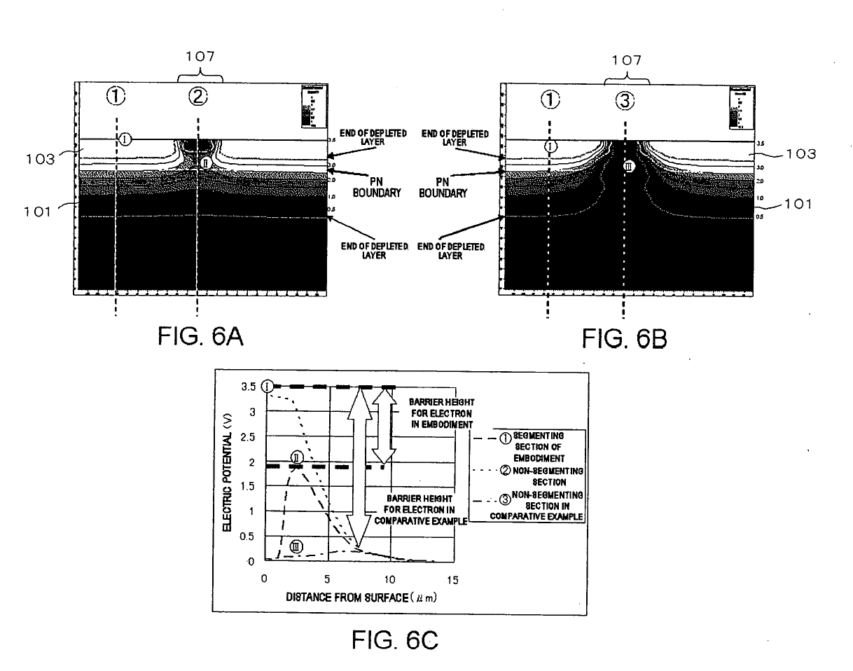

FIGS. 6A to 6C include diagrams, useful in describing the advantageous effects of the segmented photodiode of the present embodiment and the photodiode of comparative example.

FIG. 6A is a diagram of an electric potential distribution of the embodiment. FIG. 6B is a diagram of an electric potential distribution of comparative example. FIG. 6C is a graph, showing a relationship of a distance from the photosensitive surface with an electric potential. The ordinate of the graph represents electric potential (V), and the abscissa represents distance from the photosensitive surface (μm). A cross section along line I of the non-segmenting section, a cross section along line II of the segmenting section of the embodiment and a cross section along line III of the segmenting section of comparative example are shown respectively.

As shown in FIG. 6B, in the case of the photodiode of comparative example, no electric potential is distributed in both of the location right under the p type segmenting region 107 and the location around the p type segmenting region 107. The ends of the depleted layer are present only on both sides of the p type segmenting region 107 so as to pass over the p type segmenting region 107. No depleted layer is generated right under the p type segmenting region 107 and the circumference thereof. The depleted layer generated in the PN junction formed between the p type epitaxial layer 101 and the n type epitaxial layer 103 is isolated by the p type segmenting region 107. Therefore, the responsive function to light is deteriorated in the p type segmenting region 107 and circumference thereof, as compared with the n type diffusion layer 105.

Electric potential distribution in the cross section along line III is shown in the graph of FIG. 6C. In the cross section of III, no gradient is present in the electric potential, and substantially no electric field is applied. In such region without applied electric field, carrier can migrate by only diffusion. As a result, a problem of a reduction in the spectrum is generated in the location right under the p type segmenting region 107 without a depleted layer, as compared with the location right under the n type epitaxial layer 103 with a depleted layer.

On the other hand, it can be seen from FIG. 6A that an electric potential is also applied to the location right under the p type segmenting region 107 and location around the bottom surface thereof so that the depleted layer is broadened, according to the result of the electric potential distribution of the segmented photodiode of the present embodiment. The depleted layer generated in the PN junction formed between the p type epitaxial layer 101 and the n type epitaxial layer 103 is not isolated by the p type segmenting region 107, and extends within the layer of the segmented photodiode over the entire area thereof along the surface orientation. On the other hand, while the end of the depleted layer is present on only both sides of the p type segmenting region 107 in comparative example, the segmented photodiode of the present embodiment exhibits the end of the depleted layer extending to the location right under the p type segmenting region 107. Further, the PN boundary serving as the photosensitive region is electrically isolated but is not influenced by the disturbance of the p type segmenting region 107, and therefore the PN boundary in the present embodiment is further extended, as compared with comparative example.

The graph of FIG. 6C shows the electric potential distribution in the cross section along line II. A gradient of the electric potential is created in the cross section along line II, and thus a certain level of voltage or higher is applied to allow the location right under the p type segmenting region 107 being applied with an electric field. Therefore, the career (hole) generated in the p type epitaxial layer 101 right under the p type segmenting region 107 by the electric field can migrate at higher speed, and this results in a prevention of reduced spectrum of the segmented photodiode in the light irradiation to the p type segmenting region 107.

Further, as shown in FIG. 6A, the n type epitaxial layer 103 is segmented by the p type segmenting region 107. Since the bottom surface of the p type segmenting region 107 is in contact with the n type epitaxial layer 103, a reverse bias is applied to the p type epitaxial layer 101 and the n type epitaxial layer 103 to create a depleted layer in the n type region 106 right under the segmenting sections, which is then coupled with another depleted layer, which is generated by the PN junction that is formed between the p type epitaxial layer 101 and the n type epitaxial layer 103. This allows functioning as the segmented photodiode in the operation, even if the p type buried layer 102 is not provided in the p type segmenting region 107. Therefore, a defocus signal and/or a tracking error signal can be appropriately detected.

As described above, the depleted layer created by the PN junction between the p type epitaxial layer 101 and the n type epitaxial layer 103 spreads sequentially over the entire surface of the PN junction surface surrounded by the p type isolation region 108, without being isolated in the circumference of the p type segmenting region 107. Therefore, the career generated in the p type epitaxial layer 101 can travel by drift within the extended depleted layer even in the locations right under the p type segmenting region 107. Further, as compared with the case of the photodiode of comparative example, a space for the carrier migrating by diffusion so as to detour around the p type segmenting region 107 shrinks. This lead to a larger photosensitive region, which provides improved response characteristics, allowing higher speed of response of the segmented photodiode.

While the embodiments of the present invention has been fully described above in reference to the annexed figures, it is intended to present these embodiments for the purpose of illustrations of the present invention only, and various modifications other than that described above are also available. For example, the segmented photodiode of the present embodiment may constitute a photodetector. Such photodetector is capable of receiving split light beam emitted by a semiconductor laser source and reflected by optical disks such as CD, digital video disc (DVD), CD-read only memory (CD-ROM), DVD-ROM and the like by a plurality of isolated photosensitive regions to detect data stored in the optical disks.

Further, such photodetector may be employed as an element of optical reproducing units such as, for example, CD player, DVD player and the like.

A circuit element such as an npn transistor and the like may be provided in the surface of the p type semiconductor substrate in a section except the region of the segmented photodiode. Such circuit element may be isolated from the segmented photodiode via the p type isolation region 108.

It is apparent that the present invention is not limited to the above embodiment, and may be modified and changed without departing from the scope and spirit of the invention.

What is claimed is:

1. A segmented photodiode having a photosensitive region being capable of receiving light, said photosensitive region being two-dimensionally segmented into multiple areas, comprising:
a substrate of a first type conductivity;
a first semiconductor layer of the first type conductivity and formed on said substrate;
a second semiconductor layer of a second type conductivity formed on said first semiconductor layer; and
a segmenting section of first type conductivity, provided in said second semiconductor layer spaced apart from said first semiconductor layer providing segmentation of said photosensitive region,
wherein a first depleted layer is formed between said segmenting section and said first semiconductor layer by applying a reverse bias voltage, and
wherein said first depleted layer is configured to reach a second depleted layer formed in a junction surface between said second semiconductor layer and said first semiconductor layer so that said photosensitive region is electrically isolated.

2. The segmented photodiode as set forth in claim 1, wherein said segmenting section is composed of a first diffusion layer containing impurity of the first type conductivity diffused therein.

3. The segmented photodiode as set forth in claim 2, further comprising a separating unit of the first type conductivity surrounding said photosensitive region that is two-dimensionally segmented, wherein said separating unit is provided over a surface of said first semiconductor layer and a surface of said second semiconductor layer.

4. The segmented photodiode as set forth in claim 3, wherein said separating unit and said substrate constitute a common-anode.

5. The segmented photodiode as set forth in claim 3, further comprising a plurality of structural units provided therein, said structural unit being composed of said photosensitive region and said separating unit surrounding said photosensitive region.

6. The segmented photodiode as set forth in claim 3,
wherein said separating unit includes a first diffusion layer of the first type conductivity provided in said second semiconductor layer and containing impurity of first type conductivity diffused therein, and a buried layer of the first type conductivity buried in said second semiconductor layer and said first semiconductor layer, and
wherein said first diffusion layer of the first type conductivity is coupled to said buried layer of the first type conductivity in said separating unit.

7. The segmented photodiode as set forth in claim 1, wherein a second diffusion layer of the second type conductivity containing impurity of second type conductivity diffused therein is provided in the surface of said second semiconductor layer.

8. The segmented photodiode as set forth in claim 1,
wherein said photosensitive region is configured of a plurality of small regions electrically isolated by said segmenting section, and
wherein said second depleted layer is formed over the entire area of said photosensitive region.

9. The segmented photodiode as set forth in claim 1, wherein said segmenting section is cross-shaped in two-dimensional view, and provides a two-dimensional segmentation of said photosensitive region into four sections.

10. The segmented photodiode as set forth in claim 3, wherein a second diffusion layer of the second type conductivity containing impurity of second type conductivity diffused therein is provided in the surface of said second semiconductor layer.

11. The segmented photodiode as set forth in claim 3,
wherein said photosensitive region is configured of a plurality of small regions electrically isolated by said segmenting section, and
wherein said second depleted layer is formed over the entire area of said photosensitive region.

12. The segmented photodiode as set forth in claim 3, wherein said segmenting section is cross-shaped in two-dimensional view, and provides a two-dimensional segmentation of said photosensitive region into four sections.
